(19) United States
(12) Patent Application Publication
(10) Pub. No.: US 2026/0013160 A1
(43) Pub. Date: Jan. 8, 2026

(54) SEMICONDUCTOR DEVICE

(71) Applicant: ROHM CO., LTD., Kyoto (JP)

(72) Inventor: Yuto TAKIGAWA, Kyoto-shi (JP)

(73) Assignee: ROHM CO., LTD., Kyoto (JP)

(21) Appl. No.: 19/323,503

(22) Filed: Sep. 9, 2025

Related U.S. Application Data
(63) Continuation of application No. PCT/JP2024/006344, filed on Feb. 21, 2024.

(30) Foreign Application Priority Data
Mar. 16, 2023 (JP) 2023-042200

(51) Int. Cl. H10D 12/00; H10D 8/60; H10D 12/01; H10D 62/10

(52) U.S. Cl. CPC H10D 12/212; H10D 8/60; H10D 62/103; H10D 62/126; H10D 12/021

(57) ABSTRACT

A semiconductor device includes an n-type semiconductor layer, trenches, an insulating layer, a third electrode, and a p-type well region. The trenches extend in a first direction orthogonal to the thickness direction of the semiconductor layer and are spaced apart in a second direction orthogonal to the first direction. The insulating layer covers the trenches. The third electrode is formed in the insulating layer in contact with the first electrode. The well region is formed in the surface of the semiconductor layer. The well region extends in a direction intersecting the first direction and is one well regions spaced apart in the first direction. The surface of the semiconductor layer is in ohmic contact with the first electrode at the well surface of the well region. The surface of the semiconductor layer is in Schottky contact with the first electrode at an exposed surface between the well surfaces.

### CROSS-REFERENCE TO RELATED APPLICATIONS

This application is a continuation of, and claims the benefit of priority from International Application No. PCT/JP2024/006344, filed on Feb. 21, 2024, which claims the benefit of priority from Japanese Patent Application No. 2023-042200, filed on Mar. 16, 2023, the entire contents of each are incorporated herein by reference.

### BACKGROUND

### 1. Field

The present disclosure relates to a semiconductor device.

### 2. Description of Related Art

A semiconductor device includes a semiconductor substrate, a semiconductor layer formed on the semiconductor substrate, an anode formed on the semiconductor layer, and a cathode formed on the semiconductor substrate at the side opposite the semiconductor layer (see, for example, JP2012-124329A).

### BRIEF DESCRIPTION OF DRAWINGS

FIG. 1 is a schematic plan view of a semiconductor device in accordance with a first embodiment.

FIG. 2 is a schematic plan view of a semiconductor layer in the semiconductor device of FIG. 1.

FIG. 3 is a schematic cross-sectional view of the semiconductor device taken along line F3-F3 in FIG. 2.

FIG. 4 is an enlarged, schematic cross-sectional view of trenches shown in FIG. 3.

FIG. 5 is a schematic cross-sectional view of the semiconductor device taken along line F5-F5 in FIG. 2.

FIG. 6 is a schematic cross-sectional view of the semiconductor device taken along line F6-F6 in FIG. 2.

FIG. 7 is a schematic cross-sectional, perspective view showing the surface of the semiconductor layer and the shape of the trenches in the semiconductor device of FIG. 1.

FIG. 8 is a schematic cross-sectional view illustrating a manufacturing step of the semiconductor device.

FIG. 9 is a schematic cross-sectional view illustrating a manufacturing step following the step of FIG. 8.

FIG. 10 is a schematic cross-sectional view illustrating a manufacturing step following the step of FIG. 9.

FIG. 11 is a schematic cross-sectional view illustrating a manufacturing step following the step of FIG. 10.

FIG. 12 is a schematic cross-sectional view illustrating a manufacturing step following the step of FIG. 11.

FIG. 13 is a schematic cross-sectional view illustrating a manufacturing step following the step of FIG. 12.

FIG. 14 is a schematic cross-sectional view illustrating a manufacturing step following the step of FIG. 13.

FIG. 15 is a schematic cross-sectional view illustrating a manufacturing step following the step of FIG. 14.

FIG. 16 is a schematic cross-sectional view illustrating a manufacturing step following the step of FIG. 15.

FIG. 17 is a schematic cross-sectional view illustrating a manufacturing step following the step of FIG. 16.

FIG. 18 is a schematic plan view of a semiconductor layer showing the location of a well region in a modified example.

### DETAILED DESCRIPTION

Embodiments of a semiconductor device will now be described with reference to the accompanying drawings. Elements in the figures are illustrated for simplicity and clarity and have not necessarily been drawn to scale. To aid understanding, hatching lines may not be shown in the cross-sectional drawings. The accompanying drawings illustrate exemplary embodiments in accordance with the present disclosure and are not intended to limit the present disclosure.

This detailed description provides a comprehensive understanding of exemplary methods, apparatuses, and/or systems in accordance with the present disclosure. Exemplary embodiments may have different forms, and are not limited to the examples described.

### Overall Structure of Semiconductor Device

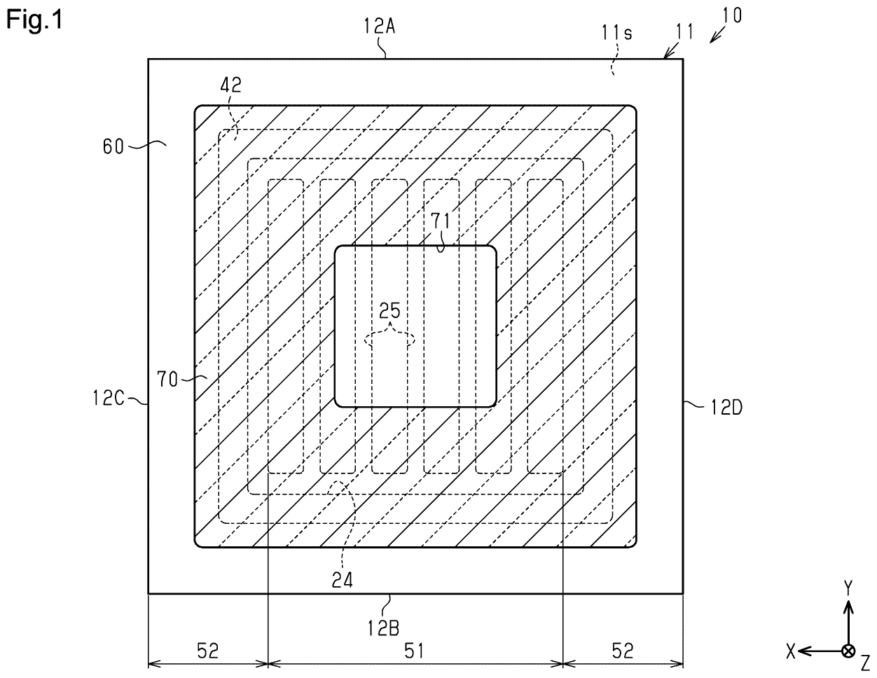

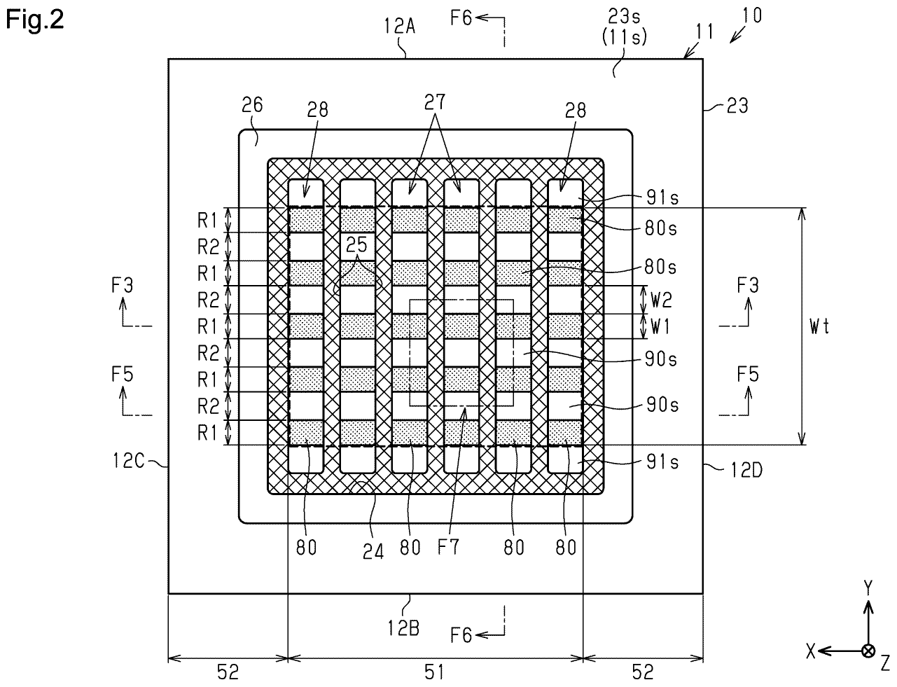

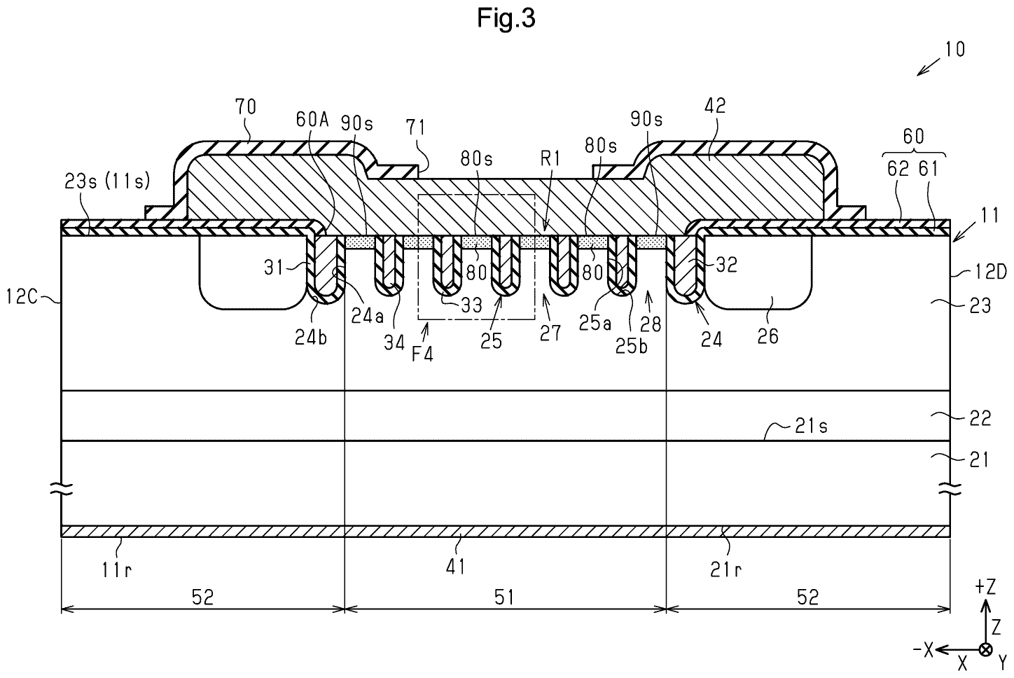

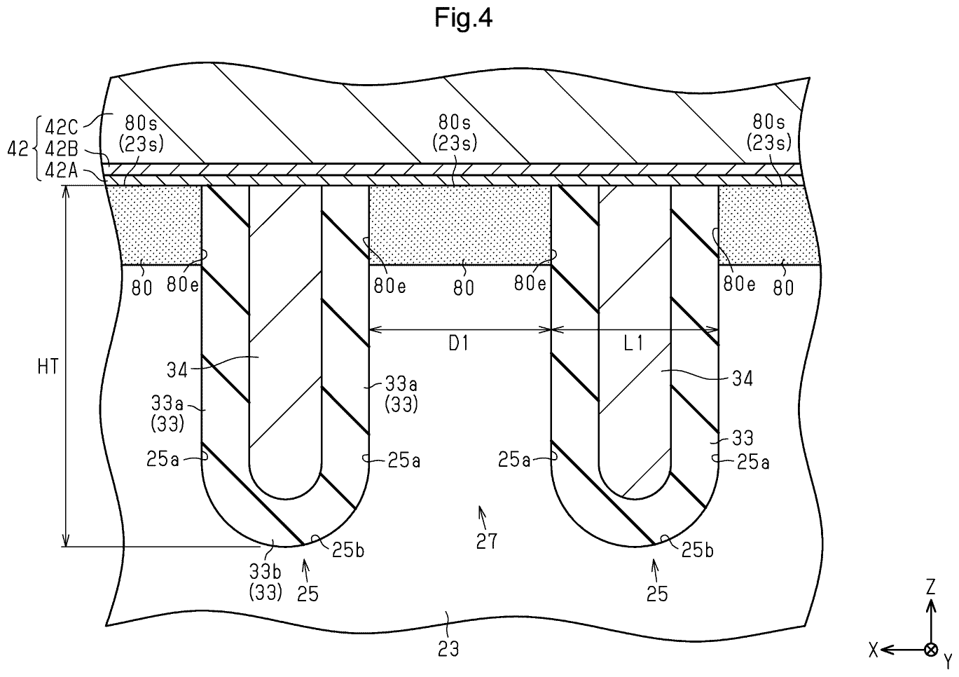

With reference to FIGS. 1 to 4, the overall structure of a semiconductor device 10 in accordance with the present embodiment will now be described. FIG. 1 schematically shows the planar structure of the semiconductor device 10. FIG. 2 schematically shows the planar structure of a semiconductor chip 11, which will be described later, in the semiconductor device 10 of FIG. 1. FIG. 3 schematically shows the cross-sectional structure taken along line F3-F3 in FIG. 2. FIG. 4 is an enlarged cross-sectional view of the range indicated by arrow F4 in FIG. 3.

In order to aid understanding in FIG. 1, a surface protective layer 70, which will be described later, is depicted with glass hatching. In order to aid understanding in FIG. 2, a surface insulating layer 60, an anode 42, and the surface protective layer 70, which will be described layer, are not shown, and an isolation trench 24 and trenches 25 are depicted with cloth hatching. For the sake of simplicity in FIGS. 3 and 4, hatching lines are omitted from parts of the semiconductor device 10.

In this specification, the X-axis, Y-axis, and Z-axis are orthogonal to one another as shown in FIG. 1. The term “plan view” as used in this specification is a view of the semiconductor device 10 taken in the Z-axis direction. Further, in FIG. 3, which shows the semiconductor device 10, the +Z direction corresponds to the upward direction, the −Z direction corresponds to the downward direction, the +X direction corresponds to the rightward direction, and the −X direction corresponds to the leftward direction. Unless otherwise indicated, the term “plan view” will refer to a view of the semiconductor device 10 taken from above along the Z-axis.

The semiconductor device 10 is a semiconductor rectifier. As shown in FIG. 1, the semiconductor device 10 includes the semiconductor chip 11. The semiconductor chip 11 is formed from, for example, a material including silicon (Si). The material of the semiconductor chip 11 is not limited to Si. In the present embodiment, the semiconductor chip 11 has the form of a flat plate. The semiconductor chip 11 includes a chip front surface 11s and a chip back surface 11r (refer to FIG. 3). Further, the semiconductor chip 11 includes first to fourth chip side surfaces 12A to 12D connecting the chip front surface 11s and the chip back surface 11r.

The shape of the semiconductor chip 11 in plan view, that is, the shape of the chip front surface 11s and the chip back surface 11r in plan view, is rectangular. The first chip side surface 12A and the second chip side surface 12B extend in the X-axis direction, and the third chip side surface 12C and the fourth chip side surface 12D extend in the Y-axis direction. The first chip side surface 12A and the second chip side surface 12B face the Y-axis direction, and the third chip side surface 12C and the fourth chip side surface 12D face the X-axis direction.

As shown in FIG. 3, the semiconductor device 10 includes a semiconductor substrate 21 located toward the chip back surface 11r in the semiconductor chip 11. The semiconductor substrate 21 includes a substrate front surface 21s and a substrate back surface 21r opposite the substrate front surface 21s. The substrate front surface 21s faces the same direction as the chip front surface 11s, and the substrate back surface 21r faces the same direction as the chip back surface 11r.

The semiconductor substrate 21 has an electrical resistivity, for example, in a range from 0.5 mΩ·cm to 3 mΩ·cm, inclusive. The semiconductor substrate 21 has an n-type impurity concentration, for example, in a range from 1×10¹⁸ cm⁻³ to 1×10²¹ cm⁻³, inclusive. The semiconductor substrate 21 has a thickness in a range from 5 μm to 300 μm, inclusive. In an example, the thickness of the semiconductor substrate 21 is in a range from 50 μm to 300 μm, inclusive. In the present embodiment, the semiconductor substrate 21 is formed by an n-type semiconductor substrate. The semiconductor substrate 21 may be, for example, a Si substrate. The material of the semiconductor substrate 21 is not limited to Si. In an example, the material of the semiconductor substrate 21 is silicon carbide (SiC).

The semiconductor device 10 includes a cathode 41 formed on the substrate back surface 21r of the semiconductor substrate 21. The cathode 41 is formed on the entire substrate back surface 21r. The cathode 41 is electrically connected to the semiconductor substrate 21. The cathode 41 is in ohmic contact with the semiconductor substrate 21 (substrate back surface 21r). The cathode 41 defines the chip back surface 11r. In the present embodiment, the cathode 41 corresponds to “the second electrode.”

The cathode 41 is formed by a stack of metal films. In an example, the cathode 41 includes a first metal film, a second metal film, and a third metal film sequentially stacked from the substrate back surface 21r.

The first metal film is formed from, for example, a material including titanium (Ti). The first metal film has a thickness, for example, in a range from 500 angstroms to 2000 angstroms, inclusive. The second metal film is formed from, for example, a material including nickel (Ni). The second metal film is, for example, thicker than the first metal film. The second metal film has a thickness, for example, in a range from 2000 angstroms to 6000 angstroms, inclusive. The third metal film is formed from, for example, a material including gold (Au). The third metal film is, for example, thinner than the second metal film. The third metal film is, for example, thinner than the first metal film. The third metal film has a thickness, for example, in a range from 100 angstroms to 1000 angstroms, inclusive. The combination of the first metal film, the second metal film, and the third metal film (first metal film/second metal film/third metal film) may be, for example, Ti/Ni/Au or Ti/Ni/silver (Ag). The cathode 41 may include a fourth metal film between the second metal film and the third metal film. The fourth metal film is formed from, for example, a material including palladium (Pd). The cathode 41 may include the first metal film and the second metal film and include no third metal film. In this case, the combination of the first metal film and the second metal film (first metal film/second metal film) may be, for example, Ti/Ni. There is no limitation to the material forming each metal film of the cathode 41.

The semiconductor device 10 includes an n-type buffer layer 22 formed on the semiconductor substrate 21, and an n-type drift layer 23 formed on the buffer layer 22. The buffer layer 22 arranged between the drift layer 23 and the semiconductor substrate 21. In other words, the drift layer 23 is formed on the semiconductor substrate 21. In the present embodiment, the drift layer 23 corresponds to “the semiconductor layer” and the n-type corresponds to “the first conductive type.”

The buffer layer 22 is in contact with the substrate front surface 21s of the semiconductor substrate 21. The buffer layer 22 is formed on the entire substrate front surface 21s. The buffer layer 22 has an n-type impurity concentration gradient that decreases in the upper direction from the semiconductor substrate 21. The buffer layer 22 has a thickness in a range within from 1 μm to 10 μm, inclusive. In the present embodiment, the buffer layer 22 is formed by an n-type epitaxial layer (Si epitaxial layer).

The drift layer 23 is in contact with the buffer layer 22. The drift layer 23 includes a surface 23s facing the same direction as the chip front surface 11s. In the present embodiment, the surface 23s of the drift layer 23 defines the chip front surface 11s. The drift layer 23 is formed on the entire buffer layer 22 in plan view. The drift layer 23 has a lower n-type impurity concentration than the semiconductor substrate 21. The n-type impurity concentration of the drift layer 23 is, for example, in a range from 1×10¹⁵ cm⁻³ to 1×10¹⁶ cm⁻³, inclusive. The drift layer 23 has an electrical resistivity, for example, in a range from 1.0 Ω·cm to 4.0 Ω·cm, inclusive. The drift layer 23 has a thickness in a range from 6 μm to 20 μm, inclusive. In the present embodiment, the drift layer 23 is formed by an n-type epitaxial layer (Si epitaxial layer).

As shown in FIGS. 1 and 2, the semiconductor device 10 includes the isolation trench 24 extending in the Z-axis direction from the surface 23s of the drift layer 23. The isolation trench 24 is located inward from the first to fourth chip side surfaces 12A to 12D in plan view. The isolation trench 24 has a closed shape in plan view. In the present embodiment, the isolation trench 24 has the shape of a substantially rectangular frame in plan view. The isolation trench 24 partitions an active region 51, which is arranged inward from the isolation trench 24, and a peripheral region 52, which is arranged outward from the isolation trench 24, in plan view. The isolation trench 24 may have any shape in plan view.

The active region 51 is where a diode is formed. The active region 51 is rectangular in plan view. The peripheral region 52 includes no diodes. In the peripheral region 52, for example, a termination structure for increasing the breakdown voltage is formed. The peripheral region 52 has a closed shape surrounding the active region 51 in plan view.

As shown in FIG. 3, the isolation trench 24 includes two side walls 24a and a bottom wall 24b connecting the two side walls 24a. The isolation trench 24 is arranged in the drift layer 23. Thus, the bottom wall 24b of the isolation trench 24 is located upward from the buffer layer 22. In the present embodiment, the bottom wall 24b is curved to bulge downward toward the buffer layer 22. The bottom wall 24b may have any shape.

The isolation trench 24 may have a depth, for example, in a range from 1 μm to 5 μm, inclusive. The isolation trench 24 may have a depth, for example, in a range from 1.5 μm to 3 μm, inclusive. The isolation trench 24 is spaced apart from the bottom of the drift layer 23 (i.e., buffer layer 22) by 1 μm or greater (preferably, 3 μm or greater). The isolation trench 24 may have a width, for example, in a range from 0.5 μm to 3 μm, inclusive. The isolation trench 24 may have a width, for example, in a range from 0.8 μm to 1.5 μm, inclusive. The width of the isolation trench 24 is the dimension in the direction orthogonal to the direction in which the isolation trench 24 extends in plan view.

The semiconductor device 10 includes an isolation insulating film 31 and an isolation electrode 32 that are arranged in the isolation trench 24.

The isolation insulating film 31 is formed along the two side walls 24a and the bottom wall 24b of the isolation trench 24. The isolation insulating film 31 is formed from, for example, a material including silicon oxide (SiO₂). The isolation insulating film 31 has a thickness, for example, in a range from 0.05 μm to 0.5 μm, inclusive. The thickness of the isolation insulating film 31 may be in a range from 0.1 μm to 0.4, inclusive. The isolation insulating film 31 defines a recessed area in the isolation trench 24.

The isolation electrode 32 fills the recessed area in the isolation trench 24. That is, the isolation electrode 32 is sandwiched by the isolation insulating film 31 and embedded in the isolation trench 24. The isolation electrode 32 includes, for example, conductive polysilicon. The conductive polysilicon may be an n-type polysilicon or a p-type polysilicon.

As shown in FIGS. 1 to 3, the active region 51 includes multiple (five in the present embodiment) trenches 25. Thus, the semiconductor device 10 includes the trenches 25. Each trench 25 extends in the Z-axis direction from the surface 23s of the drift layer 23 and also extends in the Y-axis direction. In the present embodiment, each trench 25 extends straight in the Y-axis direction. The trenches 25 are spaced apart from one another in the X-axis direction. The trenches 25 are arranged in a striped pattern in plan view. Each trench 25 is connected to the isolation trench 24 in the Y-axis direction. In the present embodiment, the Y-axis direction corresponds to “the first direction” and the X-axis direction corresponds to “the second direction.” Each trench 25 may be separated from the isolation trench 24. That is, each trench 25 does not have to be connected to the isolation trench 24.

As shown in FIGS. 3 and 4, the trenches 25 each include two side walls 25a and a bottom wall 25b connecting the two side walls 25a. The trenches 25 are arranged in the drift layer 23. That is, the bottom wall 25b of each trench 25 is located upward from the buffer layer 22. In the present embodiment, the bottom wall 25b is curved downward to bulge toward the buffer layer 22. The bottom wall 25b may have any shape.

In the present embodiment, the trenches 25 have a depth HT that is less than the depth of the isolation trench 24. In other words, the depth of the isolation trench 24 is greater than the depth HT of the trenches 25. The depth HT of the trenches 25 may be equal to the depth of the isolation trench 24.

In an example, the depth HT of the trenches 25 may be, for example, in a range from 1 μm to 5 μm, inclusive. The depth HT of the trenches 25 may be, for example, in a range from 0.8 μm to 2 μm, inclusive. The trenches 25 are spaced apart from the bottom of the drift layer 23 (i.e., buffer layer 22) by 1 μm or greater (preferably, 3 μm or greater).

The trenches 25 have a width L1 that is less than the width of the isolation trench 24. In other words, the width of the isolation trench 24 is greater than the width L1 of the trenches 25. In an example, the width L1 of the trenches 25 may be, for example, in a range from 0.1 μm to 2 μm, inclusive. The width L1 of the trenches 25 may be, for example, in a range from 0.4 μm to 1.2 μm, inclusive. The width L1 of the trenches 25 is the dimension in the direction orthogonal to the direction in which the trenches 25 extend in plan view. In the present embodiment, the trenches 25 extend in the Y-axis direction in plan view. Thus, the width of each trench 25 is the dimension of the trench 25 in the X-axis direction (second direction length).

A distance D1 between two adjacent trenches 25 in the X-direction may be, for example, in a range from 1 μm to 5 μm, inclusive. The distance D1 between two adjacent trenches 25 in the X-direction may be in a range from 2 μm to 4 μm, inclusive. Further, as shown in FIG. 3, the distance from each of the trenches 25 located at the two ends in the X-axis direction to the isolation trench 24 adjacent to these trenches 25 in the X-axis direction is substantially equal to the distance D1 between two adjacent trenches 25 in the X-direction.

The semiconductor device 10 includes an insulating layer 33 and an embedded electrode 34 that are arranged in each trench 25. In the present embodiment, the embedded electrode 34 corresponds to “the third electrode.”

As shown in FIG. 4, the insulating layer 33 is formed along the two side walls 25a and the bottom wall 25b of each trench 25. More specifically, the insulating layer 33 includes two first parts 33a formed along the side walls 25a of the trench 25, and a second part 33b formed along the bottom wall 25b of the trench 25. Each first part 33a is in contact with the drift layer 23 and a well end 80e of a well region 80, which will be described later. The second part 33b is located between the two first parts 33a and is in contact with the drift layer 23.

The insulating layer 33 is connected to the isolation insulating film 31 at the part where the corresponding trench 25 is connected to the isolation trench 24. The insulating layer 33 is formed, for example, from a material containing SiO₂. The insulating layer 33 has a thickness, for example, in a range from 0.05 μm to 0.5 μm, inclusive. The thickness of the insulating layer 33 may be in a range from 0.1 μm to 0.4 μm, inclusive. The thickness of the isolation insulating film 31 is, for example, greater than or equal to the thickness of the insulating layer 33. The insulating layer 33 defines a recessed area in each trench 25.

The embedded electrode 34 fills the recessed area in the corresponding trench 25. That is, the embedded electrode 34 is sandwiched by the insulating layer 33 and embedded in the trench 25. The embedded electrode 34 is connected to the isolation electrode 32 at the part where the corresponding trench 25 is connected to the isolation trench 24. The embedded electrode 34 includes, for example, a conductive polysilicon. The conductive polysilicon may be an n-type polysilicon or a p-type polysilicon.

As shown in FIGS. 1 to 3, the semiconductor device 10 includes a p-type peripheral well region 26 formed in a surface portion of the drift layer 23 along the isolation trench 24 within the peripheral region 52. In the present embodiment, the p-type corresponds to “the second conductive type.”

The peripheral well region 26 in formed the surface 23s of the drift layer 23. As shown in FIG. 2, the peripheral well region 26 has a closed shape in plan view. The peripheral well region 26 is an example of a termination structure and is in an electrically floating state. That is, the peripheral well region 26 is electrically isolated from the isolation electrode 32 and the embedded electrodes 34. The peripheral well region 26 has a p-type impurity concentration in a range from 1×10¹⁷ cm⁻³ to 1×10¹⁹ cm⁻³, inclusive. Referring to FIG. 3, the peripheral well region 26 has a p-type impurity concentration gradient that gradually decreases from the surface 23s of the drift layer 23 toward the bottom of the drift layer 23 (i.e., buffer layer 22).

As shown in FIG. 2, the peripheral well region 26 is adjacent to the isolation trench 24 in plan view. The peripheral well region 26 is in contact with the side walls 24a of the isolation trench 24.

As shown in FIG. 3, in the present embodiment, the thickness of the peripheral well region 26 is greater than the depth of the isolation trench 24. Further, the thickness of the peripheral well region 26 is greater than the depth of the trenches 25. The bottom of the peripheral well region 26 is spaced apart from the bottom of the drift layer 23 (i.e., buffer layer 22). In an example, the thickness of the peripheral well region 26 may be in a range from 1 μm to 5 μm, inclusive. The peripheral well region 26 may have any thickness. In an example, the thickness of the peripheral well region 26 may be less than the depth of the isolation trench 24. Further, the peripheral well region 26 may cover a part of the bottom wall 24b of the isolation trench 24.

The peripheral well region 26 has a greater width than the isolation trench 24. The width of the peripheral well region 26 is greater than the width L1 of the trenches 25. The width of the peripheral well region 26 is greater than the thickness of the peripheral well region 26. In an example, the width of the peripheral well region 26 may be in a range from 2 μm to 20 μm, inclusive. Further, in an example, the width of the peripheral well region 26 may be in a range from 5 μm to 15 μm, inclusive. The width of the peripheral well region 26 is the dimension in the direction orthogonal to the direction in which the peripheral well region 26 extends in plan view.

As shown in FIGS. 1 and 3, the semiconductor device 10 includes the surface insulating layer 60 that covers the surface 23s of the drift layer 23 in the peripheral region 52. The surface insulating layer 60 has a closed shape corresponding to the shape of the peripheral region 52 in plan view. More specifically, as shown in FIG. 3, the surface insulating layer 60 includes a through hole 60A exposing the active region 51. The inner edge of the surface insulating layer 60 overlaps parts of the isolation electrode 32 in plan view. That is, the surface insulating layer 60 overlaps parts of the upper surface of the isolation electrode 32. The surface insulating layer 60 covers the entire peripheral well region 26. This insulates the peripheral well region 26 from the outer side.

The surface insulating layer 60 is formed by a first insulating film 61 and a second insulating film 62.

The first insulating film 61 is in contact with the surface 23s of the drift layer 23. The first insulating film 61 is formed from, for example, a material including SiO₂. In an example, the first insulating film 61 is formed by a field oxide film including the oxide of the drift layer 23.

The second insulating film 62 is formed on the first insulating film 61. The second insulating film 62 includes a silicon oxide film having properties that differ from the first insulating film 61. In an example, the second insulating film 62 may include, for instance, at least one of a phosphorus silicate glass (PSG) film and an undoped silicate glass (USG) film. A PSG is a silicon oxide film including P, and a USG is an impurity-free silicon oxide film. The second insulating film 62 may be formed by a stack of a PSG film and a USG film.

The first insulating film 61 has a thickness in a range from 1000 angstroms to 5000 angstroms, inclusive. The thickness of the first insulating film 61 may be in a range from 1500 angstroms to 3500 angstroms, inclusive. The second insulating film 62 has a thickness in a range from 1000 angstroms to 6000 angstroms, inclusive. The thickness of the second insulating film 62 may be in a range from 2500 angstroms to 4500 angstroms, inclusive.

The semiconductor device 10 includes the anode 42 formed on the surface 23s of the drift layer 23. The anode 42 corresponds to “the first electrode.”

The anode 42 extends over both the active region 51 and the peripheral region 52. In detail, the anode 42 extends over the entire active region 51. As shown in FIG. 1, the anode 42 is located inward from the first to fourth chip side surfaces 12A to 12D in the peripheral region 52 in plan view. That is, the anode 42 is located in the inner part of the peripheral region 52. The anode 42 is rectangular in plan view.

As shown in FIG. 3, the anode 42 is connected to both the isolation electrode 32 and the embedded electrodes 34. More specifically, the anode 42 is in ohmic contact with both the isolation electrode 32 and the embedded electrodes 34. This electrically connects the anode 42 to both the isolation electrode 32 and the embedded electrodes 34.

In the peripheral region 52, the anode 42 is formed on the surface insulating layer 60. Thus, in the peripheral region 52, the anode 42 is insulated from the drift layer 23 and the peripheral well region 26. In the present embodiment, the outer edges of the anode 42 are located outward from the peripheral well region 26.

As shown in FIG. 4, the anode 42, for example, is formed by a stack of a first electrode film 42A, a second electrode film 42B, and a third electrode film 42C. The first electrode film 42A is in contact with the surface 23s of the drift layer 23. The second electrode film 42B is formed on the first electrode film 42A, and the third electrode film 42C is formed on the second electrode film 42B. The second electrode film 42B is thicker than the first electrode film 42A. The third electrode film 42C is thicker than the first electrode film 42A and the second electrode film 42B. The thickness of the first electrode film 42A may be, for example, in a range from 50 angstroms to 1000 angstroms, inclusive. The thickness of the first electrode film 42A may be, for example, in a range from 250 angstroms to 500 angstroms, inclusive. The thickness of the second electrode film 42B may be in a range from 500 angstroms to 5000 angstroms, inclusive. The thickness of the second electrode film 42B may be in a range from 1500 angstroms to 4500 angstroms, inclusive. The thickness of the third electrode film 42C may be in a range from 0.5 μm to 10 μm, inclusive. The thickness of the third electrode film 42C may be in a range from 2.5 μm to 7.5, inclusive.

The electrode material of the first electrode film 42A may include at least one of magnesium (Mg), aluminum (Al), titanium (Ti), vanadium (V), chromium (Cr), manganese (Mn), cobalt (Co), nickel (Ni), copper (Cu), zirconium (Zr), niobium (Nb), molybdenum (Mo), palladium (Pd), silver (Ag), indium (In), tin (Sn), tantalum (Ta), tungsten (W), platinum (Pt), and gold (Au). The first electrode film 42A may be formed by a single film or a stack of films. The films may be formed from different electrode materials. In an example, the first electrode film 42A may include, for instance, Mo.

The second electrode film 42B is formed by a metal barrier film, for example, a Ti metal film. The electrode material of the second electrode film 42B may include at least one Ti and titanium nitride (TiN). The second electrode film 42B is formed by a single film formed from Ti or TiN. The second electrode film 42B may be formed by a stack of Ti films or TiN films. In the present embodiment, the second electrode film 42B is formed by a material including TiN.

The third electrode film 42C defines an electrode pad and is formed from, for example, a material including at least one of Cu and Al. The electrode material of the third electrode film 42C includes at least one of Cu, Al, an aluminum-copper alloy (AlCu), an aluminum-silicon alloy (AlSi), and an aluminum-silicon-copper alloy (AlSiCu). In the present embodiment, the third electrode film 42C is formed from a material including Al.

The semiconductor device 10 includes the surface protective layer 70 formed on the surface insulating layer 60 so as to cover the anode 42.

As shown in FIG. 1, the outer edges of the surface protective layer 70 are spaced apart from the first to fourth chip side surfaces 12A to 12D. As shown in FIG. 3, the surface protective layer 70 extends continuously from the upper surface to the side surfaces of the anode 42. The surface protective layer 70 extends outward from the anode 42. The surface protective layer 70 includes an opening 71 exposing the central part of the anode 42. The part of the anode 42 exposed from the opening 71 defines an electrode pad bonded to a connection member such as a wire.

The surface protective layer 70 is formed by a single layer of an inorganic insulating film. The surface protective layer 70 is formed from an insulator differing from that of the surface insulating layer 60. The surface protective layer 70 may include, for example, at least one of SiN and silicon oxynitride (SiON). The surface protective layer 70 may have a thickness, for example, in a range of 0.2 μm to 1.5 μm, inclusive. The thickness of the surface protective layer 70 may be, for example, 0.6 μm to 1.2 μm, inclusive. The surface protective layer 70 may be formed by an organic insulating film of polyimide.

### Well Region

As shown in FIG. 2, the semiconductor device 10 includes the well regions 80, which are of the p-type, formed in the surface portion of the drift layer 23 within the active region 51. In the present embodiment, the p-type corresponds to “the second conductive type.”

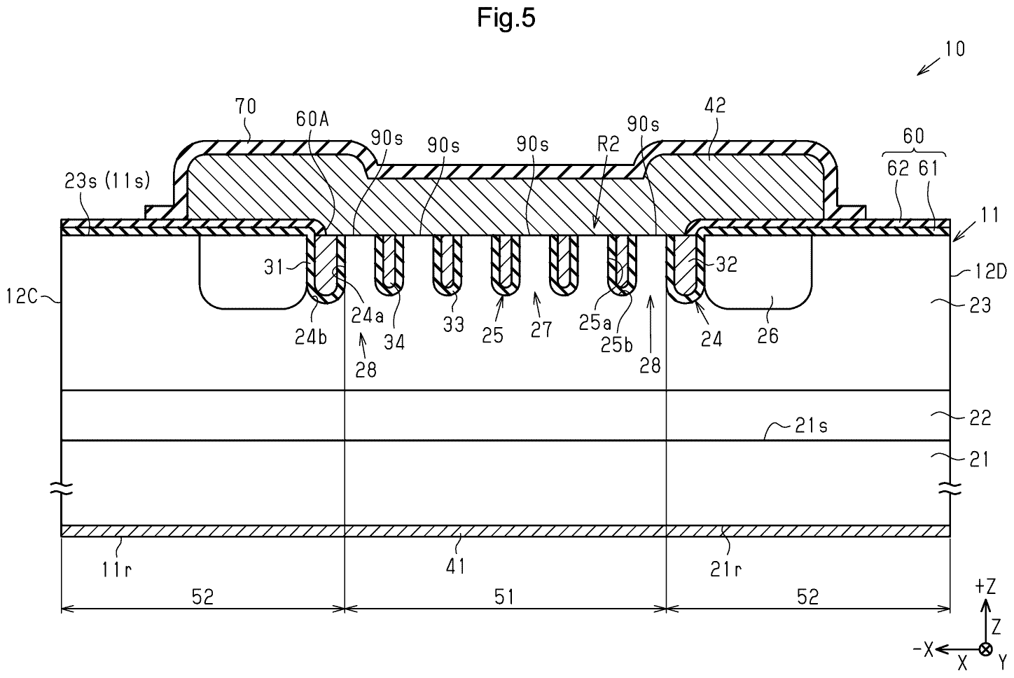

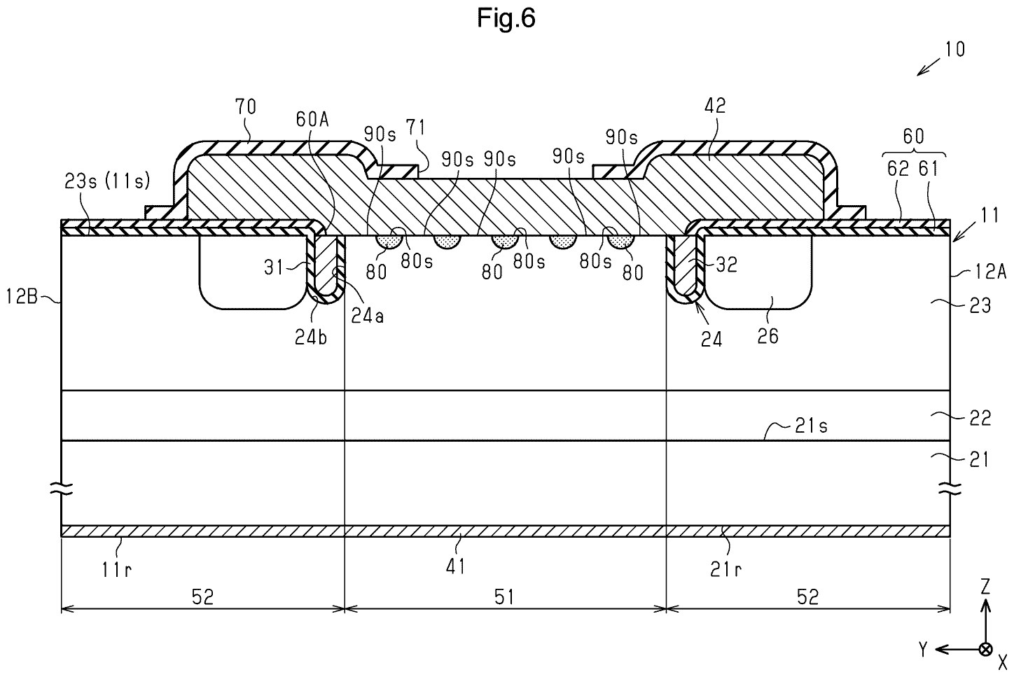

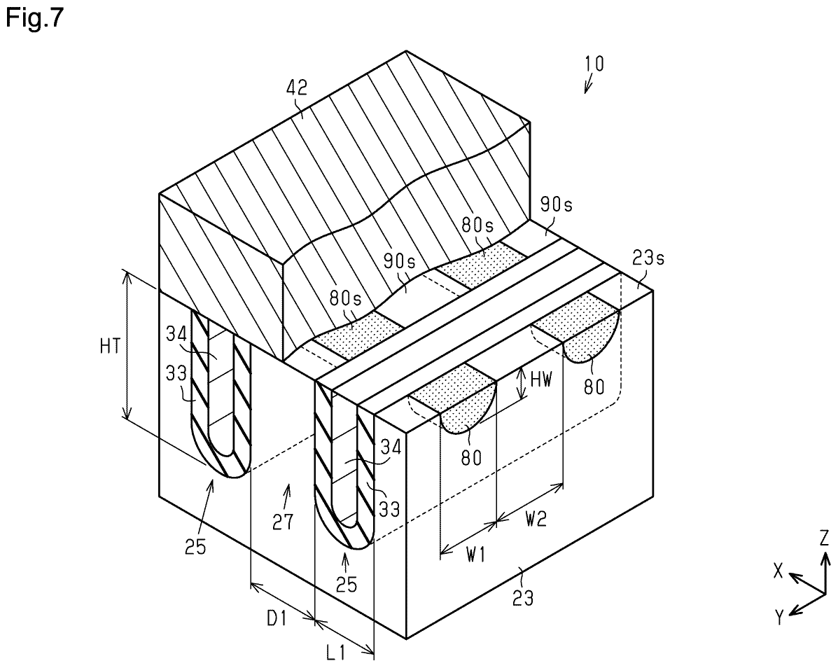

With reference to FIGS. 1 to 7, the well regions 80 will now be described in detail. FIG. 5 schematically shows the cross-sectional structure taken along line F5-F5 in FIG. 2. FIG. 6 schematically shows the cross-sectional structure taken along line F6-F6 in FIG. 2. FIG. 7 is a perspective, cross-sectional view illustrating the area indicated by arrow F6 in FIG. 2 In order to aid understanding in FIGS. 1 to 7, the well regions 80 are depicted with dot hatching. For the sake of simplicity, hatching lines are omitted from parts of the semiconductor device 10 in FIGS. 4 to 7. In order to aid understanding in FIG. 7, the lower part of the drift layer 23 and the upper part of the anode 42 are not shown.

As shown in FIGS. 2 and 3, the well regions 80 are formed in the surface 23s of the drift layer 23 within the active region 51. The well regions 80 are each formed in the drift layer 23 in a region between two adjacent trenches 25 in the X-axis direction (hereinafter, referred to as the inter-trench regions 27). The well regions 80 may also be formed in the drift layer 23 in a region between the isolation trench 24 and the trench 25 that is adjacent in the X-axis direction (hereinafter, referred to as the trench-sideward regions 28). FIGS. 2 and 3 show an example in which both the inter-trench regions 27 and the trench-sideward regions 28 include the well regions 80. The well regions 80 may be omitted from the trench-sideward regions 28. Alternatively, the well regions 80 may be arranged in only one of the two trench-sideward regions 28.

As shown in FIG. 2, the well regions 80 extend in the X-axis direction and are spaced apart in the Y-axis direction in each of the inter-trench regions 27 and the trench-sideward regions 28. In an example, the well regions 80 are spaced apart at equal intervals in the Y-axis direction.

In the inter-trench regions 27 and the trench-sideward regions 28, the well regions 80 are aligned in a direction orthogonal to the Y-axis direction (i.e., X-axis direction) with the trenches 25 located in between. Thus, the well region 80 extends in the X-axis direction and spans across one of the trenches 25 without overlapping with the one of the trenches 25. In other words, the well regions 80 spaced apart in the Y-axis direction extend in the X-axis direction and span across one of the trenches 25 without overlapping with the one of the trenches 25 so as to be arranged in a striped pattern with spacing in the Y-axis direction.

Each well region 80 is formed extending over the entire corresponding inter-trench region 27 in the X-axis direction. Further, the well regions 80 may be formed in the inter-trench regions 27 and the trench-sideward regions 28 so as to extend over the entire corresponding region in the X-axis direction. The direction in which the well regions 80 are aligned with the trenches 25 located in between is not limited to the direction orthogonal to the Y-axis direction (i.e., X-axis direction). For example, the direction in which the well regions 80 are aligned with the trenches 25 located in between may be a direction intersecting to the X-axis direction and the Y-axis direction.

As shown in FIG. 4, the well regions 80 each include a well surface 80s exposed from the surface 23s of the drift layer 23. The well surface 80s defines part of the surface 23s of the drift layer 23. The well surface 80s is in contact with the anode 42 within the active region 51. More specifically, the well surface 80s is in ohmic contact with the anode 42 in the active region 51.

In each well region 80, each of the two ends in the X-axis direction, which is the direction in which the well region 80 extends, defines the well end 80e. The well ends 80e of the well regions 80 in the inter-trench regions 27 are in contact with the insulating layer 33 of the trenches 25. Thus, each well region 80 in the inter-trench regions 27 is in contact with the two trenches 25 that sandwich the well region 80 in the X-axis direction. The well ends 80e of the well regions 80 in the trench-sideward regions 28 are in contact with the isolation insulating film 31 of the isolation trench 24 and the insulating layer 33 of the adjacent trench 25. Thus, each well region 80 in the trench-sideward regions 28 is in contact with the isolation trench 24 and the trench 25 that sandwich the well region 80 in the X-axis direction.

As shown in FIGS. 6 and 7, in an example, the well regions 80 are semi-circular as viewed in the X-axis direction. More specifically, the well regions 80 are each formed so that the width (dimension in Y-axis direction) is the maximum at the well surface 80s and gradually decreases as the well surface 80s becomes farther. In an example, the maximum width of each well region 80, that is, the width W1 of the well surface 80s, is equal to two times the maximum thickness HW of the well region 80. The width W1 and the thickness HW will be described in detail later.

As shown in FIGS. 2 and 7, the surface 23s of the drift layer 23, where the inter-trench regions 27 and the trench-sideward regions 28 are located, includes the exposed surface 90s located between the well surfaces 80s of two adjacent ones of the well regions 80. The exposed surface 90s is in contact with the anode 42 in the active region 51. More specifically, the exposed surface 90s is in Schottky contact with the anode 42 in the active region 51. In the present embodiment, in the surface 23s of the drift layer 23, parts 91s between the isolation trench 24 and the well surfaces 80s of the well regions 80 that are located at the two ends in the Y-axis direction have no exposed surface 90s.

The surface 23s of the drift layer 23, where the inter-trench regions 27 and the trench-sideward regions 28 are located, includes parts defining the well surfaces 80s and parts defining the exposed surfaces 90s. As shown in FIGS. 6 and 7, the surface 23s of the drift layer 23, where the inter-trench regions 27 and the trench-sideward regions 28 are located, is in ohmic contact with the anode 42 at the well surfaces 80s and in Schottky contact with the anode 42 at the exposed surfaces 90s. In other words, in the active region 51, the anode 42 is in ohmic contact with the well surfaces 80s and in Schottky contact with the exposed surfaces 90s.

As shown in FIG. 7, the width W1 of each well surface 80s in the Y-axis direction (i.e., first direction length W1) may be, for example, in a range from 0.1 μm to 10 mm, inclusive. The width W1 may be in the range described below. As shown in FIG. 2, the well surfaces 80s and the exposed surfaces 90s, which are arranged next to one another in the Y-axis direction, each have a width in the Y-axis direction that totals to a total width Wt (total first direction length). In this case, the width W1 may be, for example, in a range from 0.00001 Wt to 0.99999 Wt, inclusive. The total width Wt may be, for example, in a range from 0.1 mm to 10 mm, inclusive. Each well surface 80s may have the same width W1. Alternatively, one or more well surfaces 80s may have a different width W1.

In an example, the width W1 of each well surface 80s is less than the distance D1 between two adjacent trenches 25 in the X-direction. In an example, the width W1 of each well surface 80s is greater than the distance D1 between two adjacent trenches 25 in the X-direction. In one example, the width W1 of each well surface 80s is equal to the distance D1 between two adjacent trenches 25 in the X-direction. In one example, the width W1 of each well surface 80s is greater than the width L1 of each trench 25. In one example, the width W1 of each well surface 80s is less than the width L1 of each trench 25. In one example, the width W1 of each well surface 80s is equal to the width L1 of each trench 25.

The thickness HW of each region 80 in the Z-axis direction may be, for example, in a range from 0.01 μm to 5 μm, inclusive. In an example, the thickness HW of each well region 80 is less than the depth HT of each trench 25. For example, the thickness HW of each well region 80 is less than or equal to one-half of the depth HT. The thickness HW may be less than or equal to one-third of the depth HT. Each well region 80 may have the same thickness HW. Alternatively, one or more well regions 80 may have a different thickness HW. The thickness HW of each well region 80 refers to the maximum thickness of the well region 80.

In the surface 23s of the drift layer 23, the width W2 of each exposed surface 90s in the Y-axis direction may be, for example, in a range from 0.1 μm to 10 mm, inclusive. The width W2 may be, for example, in a range from 0.00001 Wt to 0.99999 Wt, inclusive (refer to FIG. 2). The width W2 may be defined as the distance between two well regions 80 in the Y-axis direction. Each exposed surface 90s may have the same the width W2. Alternatively, one or more exposed surfaces 90s may have a different width W2. When the well regions 80 are spaced apart at equal intervals in the Y-axis direction, the exposed surfaces 90s all have the same width W2.

The area of each well surface 80s in the inter-trench regions 27 and the trench-sideward regions 28 totals to a total area S1. The area of each exposed surface 90s in the inter-trench regions 27 and the trench-sideward regions 28 totals to a total area S2. The total area S1 is the total area of the well surfaces 80s within the range indicated by the dashed box in FIG. 2. The total area S2 is the total area of the exposed surfaces 90s within the range indicated by the dashed box in FIG. 2. The area ratio (S1/S2) of the total area S1 of the well surfaces S1 to the total area S2 of the exposed surfaces 90s satisfies 0<S1/S2≤100. The area ratio (S1/S2) is, for example, greater than or equal to 0.00001 or greater than or equal to 0.0001.

In an example, the total area S1 of the well surfaces 80s is greater than the total area S2 of the exposed surfaces 90s. In this case, the area ratio (S1/S2) of the total area S1 of the well surfaces S1 to the total area S2 of the exposed surfaces 90s satisfies, for example, 1<S1/S2≤100. In another example, the total area S1 of the well surfaces 80s is less than the total area S2 of the exposed surfaces 90s. In this case, the area ratio (S1/S2) of the total area S1 of the well surfaces S1 to the total area S2 of the exposed surfaces 90s satisfies, for example, 0<S1/S2<1. In a further example, the total area S1 of the well surfaces 80s is equal to the total area S2 of the exposed surfaces 90s (area ratio S1/S2=1).

The total area S1 of the well surfaces 80s and the total area S2 of the exposed surfaces 90s may be adjusted by, for example, changing the width W1 of each well surface 80s and the width W2 of each exposed surface 90s. The width W1 of each well surface 80s and the width W2 of each exposed surface 90s is variable. The width W1 of each well surface 80s may be greater than the width W2 of each exposed surface 90s. The width W1 of each well surface 80s may be less than the width W2 of each exposed surface 90s. The width W1 of each well surface 80s may be equal to the width W2 of each exposed surface 90s.

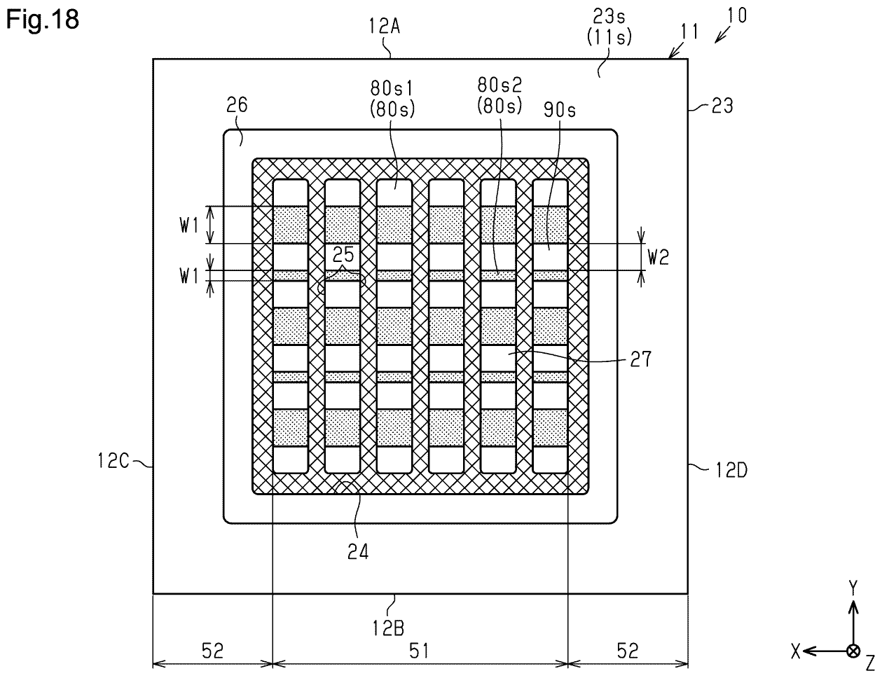

One or more well surfaces 80s may have a different width W1. One or more exposed surface 90s may have a different width W2. In one example, as shown in FIG. 18, the well surfaces 80s may have different widths W1. FIG. 18 shows well surfaces 80s1 having a relatively large width W1 and well surfaces 80s2 having a relatively small width W1. The well surfaces 80s1 and the well surfaces 80s2 are arranged alternately in the Y-axis direction. Further, the exposed surfaces 90s have the same width W2.

The p-type impurity concentration of the well regions 80 is, for example, in a range from 1×10¹⁶ cm⁻³ to 1×10¹⁸ cm⁻³, inclusive. The n-type impurity concentration of the drift layer 23 is lower than the p-type impurity concentration of the well regions 80.

### Method for Manufacturing the Semiconductor Device

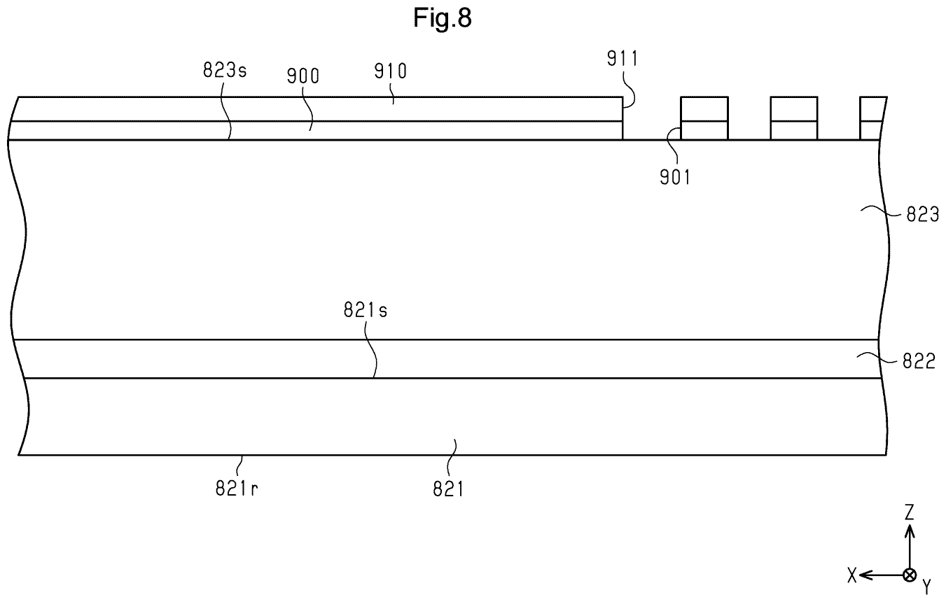

With reference to FIGS. 8 to 17, an example of a method for manufacturing the semiconductor device 10 will now be described. FIGS. 8 to 17 are cross-sectional views showing parts of the active region 51 and the peripheral region 52 to illustrate the method for manufacturing the semiconductor device 10.

Referring to FIG. 8, a semiconductor wafer 821, which acts as a base of the semiconductor substrate 21, is prepared. The semiconductor wafer 821 includes a wafer front surface 821s and a wafer back surface 821r opposite the wafer front surface 821s. In an example, the semiconductor wafer 821 is a Si wafer. In the method for manufacturing the semiconductor device in accordance with the present embodiment, the semiconductor wafer 821 corresponds to “the semiconductor substrate,” the wafer front surface 821s corresponds to “the substrate front surface,” and the wafer back surface 821r corresponds to “the substrate back surface.”

Then, epitaxy is performed to grow crystals of Si from the wafer front surface 821s of the semiconductor wafer 821. This forms a buffer layer 822, which has a predetermined n-type impurity concentration, and a drift layer 823, which has a predetermined n-type impurity concentration, in this order. In the method for manufacturing the semiconductor device in accordance with the present embodiment, the drift layer 823 corresponds to “the semiconductor layer.”

A mask 900 is formed on a surface 823s of the drift layer 823. The mask 900 is formed by a SiO₂ film. The mask 900 may be formed through at least one of chemical vapor deposition (CVD) and thermal oxidation. In the present embodiment, the mask 900 is formed through thermal oxidation.

A first resist mask 910 having a predetermined pattern is formed on the mask 900. The first resist mask 910 includes openings 911 corresponding to regions where the isolation trench 24 and the trenches 25 (refer to FIG. 3) are formed in the surface 823s of the drift layer 823.

Etching is performed through the openings 911 of the first resist mask 910 to form openings 901 in the exposed parts of the mask 900. The openings 901 and 911 expose the regions where the isolation trench 24 and the trenches 25 are formed in the surface 823s of the drift layer 823. The first resist mask 910 is removed after the formation of the openings 901 in the mask 900.

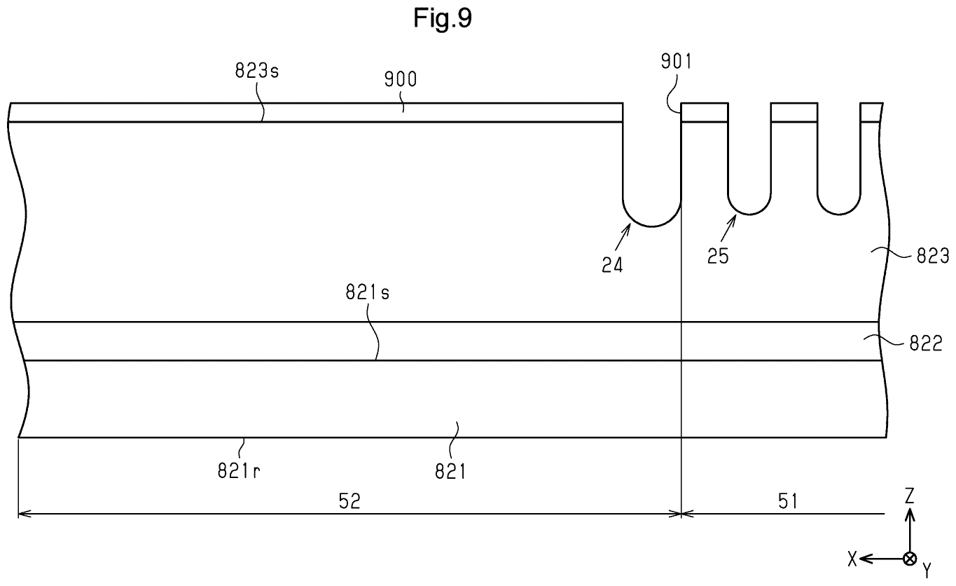

Referring to FIG. 9, etching is performed with the mask 900 to remove regions corresponding to the isolation trench 24 and the trenches 25 from the surface 823s of the drift layer 823. This forms the isolation trench 24 and the trenches 25. The isolation trench 24 extends in the Z-axis direction from the surface 823s of the drift layer 823 and has the form of a rectangular frame in plan view. Each trench 25 extends in the Z-axis direction from the surface 823s of the drift layer 823 and also extends in the Y-axis direction. Each trench 25 is connected to the isolation trench 24. The trenches 25 are spaced apart from one another in the X-axis direction.

The isolation trench 24 partitions the active region 51 and the peripheral region 52. The etching may be at least one of wet etching and dry etching. In the present embodiment, dry etching is performed. Dry etching may be, for example, reactive ion etching (RIE). The mask 900 is removed after the formation of the isolation trench 24 and the trenches 25.

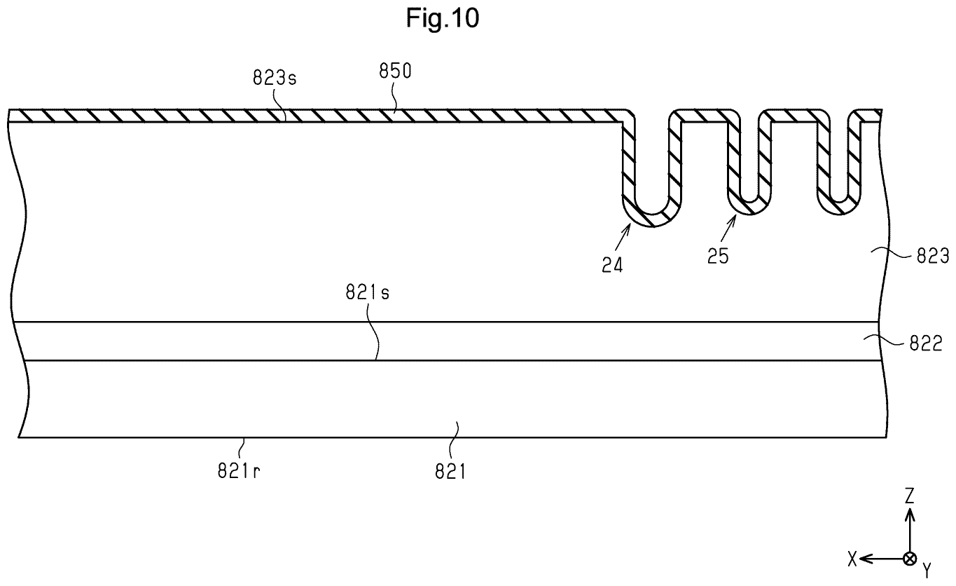

As shown in FIG. 10, at least one of CVD or thermal oxidation is performed to form a first base insulating film 850 on the surface 823s of the drift layer 823, the inner walls of the isolation trench 24, and the inner walls of the trenches 25. In the present embodiment, thermal oxidation is performed to form the first base insulating film 850. The first base insulating film 850 is a field oxide film. The first base insulating film 850 is formed by a SiO₂ film. The first base insulating film 850 acts as the base of the isolation insulating film 31, the insulating layer 33 of the trenches 25, and the first insulating film 61 (refer to FIG. 3). The first base insulating film 850 grows by absorbing n-type impurities in the vicinity of the drift layer 823. Thus, the first base insulating film 850 includes the n-type impurities of the drift layer 823 In the method for manufacturing the semiconductor device in accordance with the present embodiment, the first base insulating film 850 corresponds to “the insulating layer.”

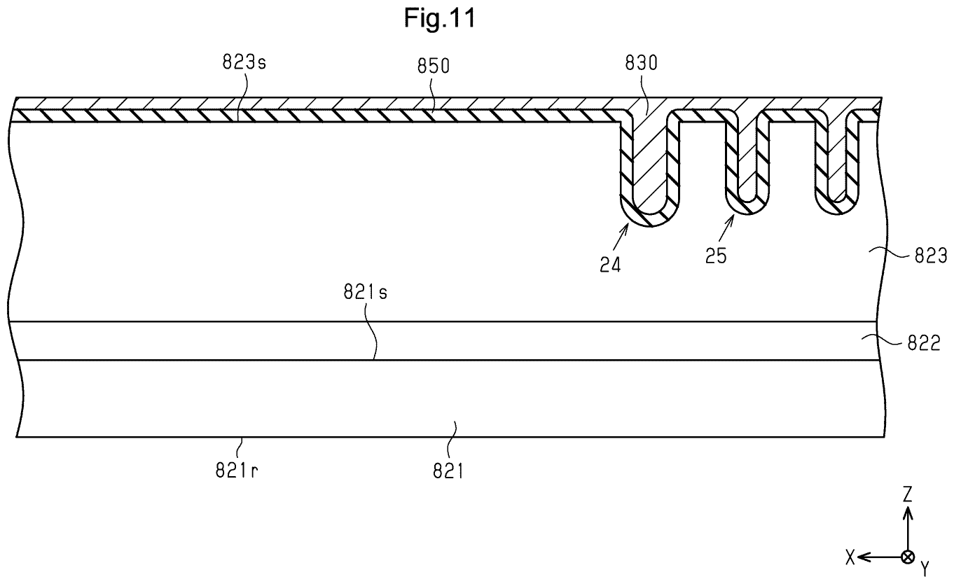

As shown in FIG. 11, CVD is performed to form a first base electrode film 830 on the first base insulating film 850. The first base electrode film 830 acts as a base of the isolation electrode 32 and the embedded electrodes 34 (refer to FIG. 3). The first base electrode film 830 is formed on the entire surface 823s of the drift layer 823 and fills a first recessed area formed in the isolation trench 24 by the first base insulating film 850 and second recessed areas formed in the trenches 25 by the first base insulating film 850. The first base electrode film 830 is formed by, for example, a conductive polysilicon film.

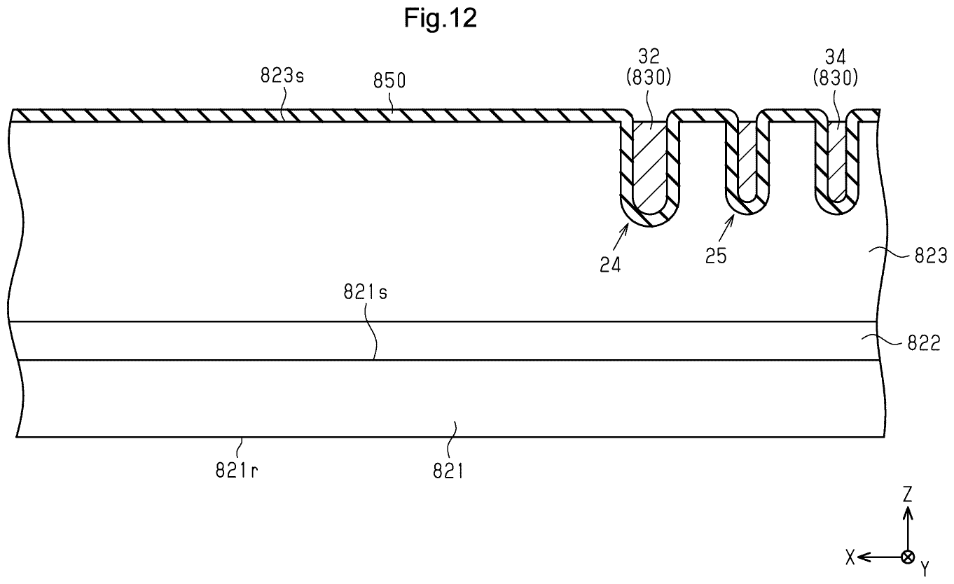

As shown in FIG. 12, etching is performed to remove parts of the first base electrode film 830 that are not embedded in the first recessed area and the second recessed areas. This forms the isolation electrode 32 and the embedded electrodes 34. The etching may be, for example, at least one of wet etching and dry etching. In the method for manufacturing the semiconductor device in accordance with the present embodiment, the embedded electrodes 34 each correspond to “the third electrode.”

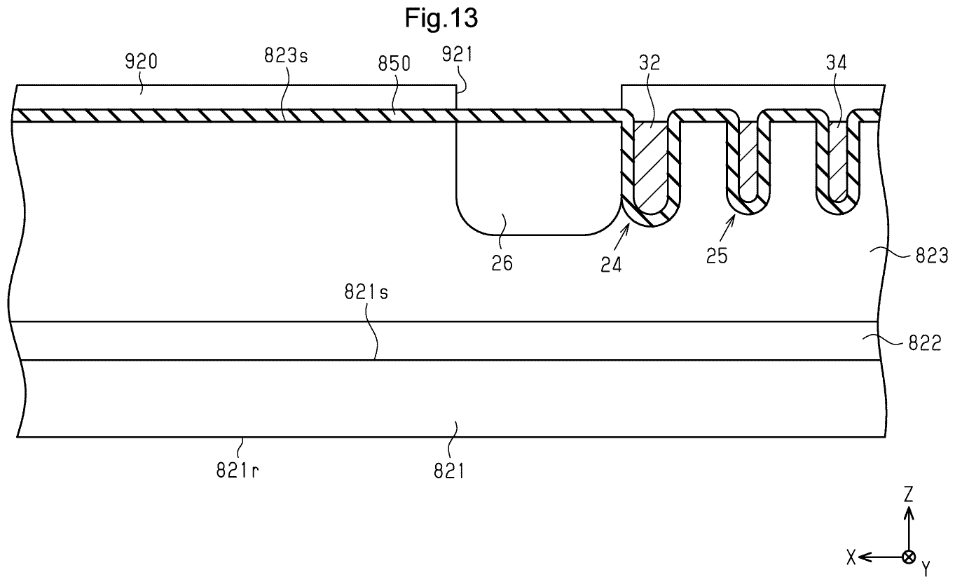

As shown in FIG. 13, a second resist mask 920 having a predetermined pattern is formed on the first base insulating film 850. The second resist mask 920 includes an opening 921 exposing regions where the peripheral well region 26 is formed in the surface 823s of the drift layer 823.

Then, ion implantation is performed with the second resist mask 920 to implant p-type impurities in the surface 823s of the drift layer 823. The p-type impurities are implanted through the first base insulating film 850 to the surface portion of the drift layer 823. Further, a drive-in process is performed to diffuse the p-type impurities, which are implanted in the surface portion of the drift layer 823, in the width direction (X-axis direction) and depth direction (Z-axis direction) of the drift layer 823. The peripheral well region 26 is formed through the steps described above. The second resist mask 920 is removed after the formation of the peripheral well region 26.

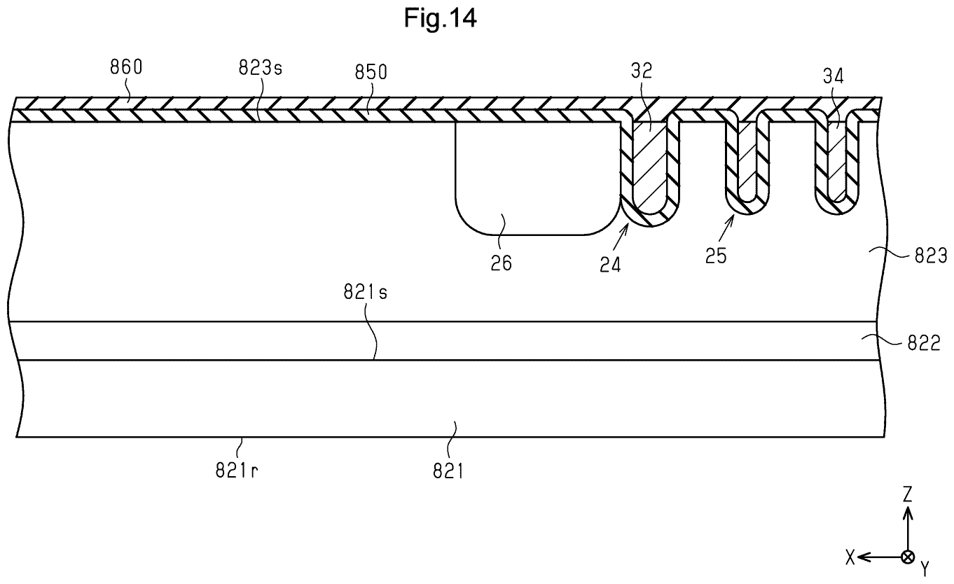

As shown in FIG. 14, CVD is performed to form a second base insulating film 860 on the first base insulating film 850, the isolation electrode 32, and the embedded electrodes 34. The second base insulating film 860 acts as the base of the second insulating film 62. The second base insulating film 860 is formed by an insulative material differing from that of the first base insulating film 850. More specifically, the second base insulating film 860 is formed by a SiO₂ film having properties that differ from the first base insulating film 850. The second base insulating film 860 includes, for example, at least one of a PSG film and a USG film.

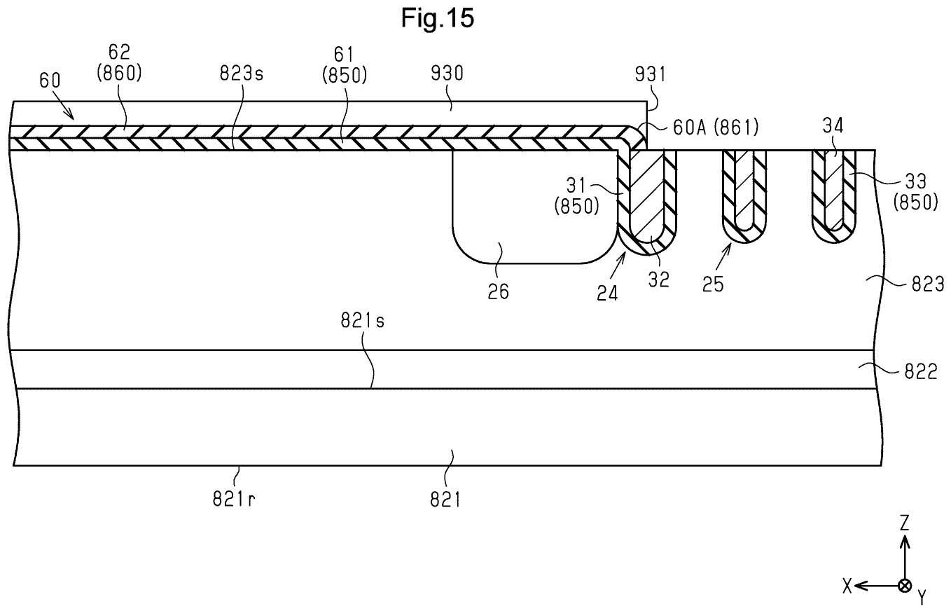

As shown in FIG. 15, a third resist mask 930 having a predetermined pattern is formed on the second base insulating film 860. The third resist mask 930 includes an opening 931 exposing a region where the through hole 60A of the surface insulating layer 60 is formed in the second base insulating film 860. Etching is performed with the third resist mask 930 to remove the part of the second base insulating film 860 exposed from the opening 931. The etching may be at least one of wet etching and dry etching. In the present embodiment, dry etching (e.g., RIE) is performed. This forms a through hole 861 in the second base insulating film 860.

Further etching is performed with the third resist mask 930 to remove the part of the first base insulating film 850 exposed from the opening 931 and the through hole 861. The etching may be at least one of wet etching and dry etching. In the present embodiment, dry etching (e.g., RIE) is performed. This separates the first base insulating film 850 into the isolation insulating film 31, the insulating layer 33, and the first insulating film 61. Further, the second base insulating film 860 becomes the second insulating film 62. This forms the surface insulating layer 60, which is a stack of the first insulating film 61 and the second insulating film 62, on the surface 823s of the drift layer 823. The third resist mask 930 is removed after patterning the first base insulating film 850 and the second base insulating film 860.

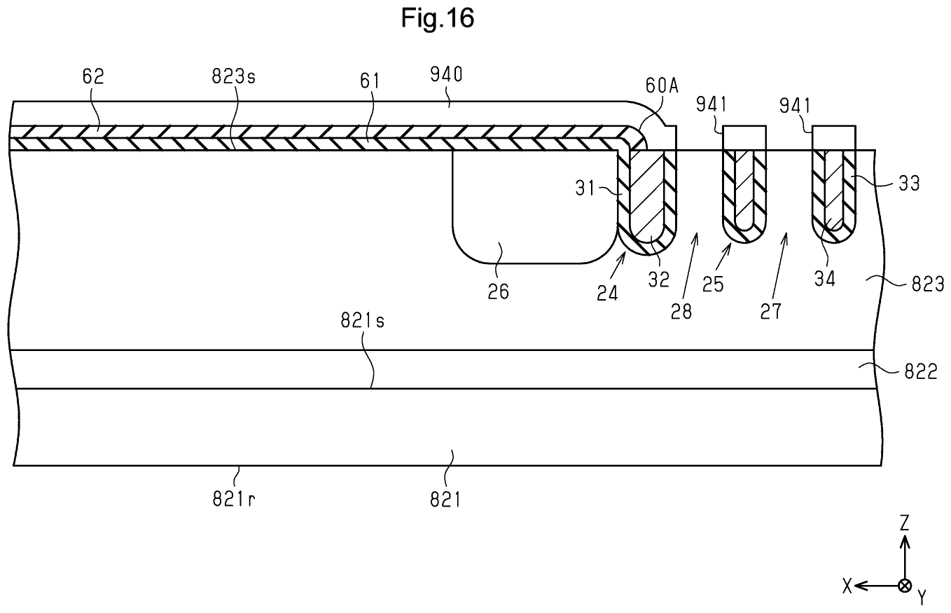

As shown in FIG. 16, a fourth resist mask 940 having a predetermined pattern is formed on the surface insulating layer 60. The fourth resist mask 940 includes openings 941 exposing parts of the inter-trench regions 27 and the trench-sideward regions 28 in the surface 823s of the drift layer 823. The openings 941 of the fourth resist mask 940 are formed for each of the inter-trench regions 27 and each of the trench-sideward regions 28. The fourth resist mask 940 exposes the parts of the inter-trench regions 27 and the trench-sideward regions 28 where the well surfaces 80s are formed through the openings 941, and entirely covers the parts where the well surfaces 80s are not formed.

Then, ion implantation is performed with the fourth resist mask 940 to implant p-type impurities in the surface 823s of the drift layer 823. More specifically, p-type impurities are implanted in the inter-trench regions 27 and the trench-sideward regions 28 through the openings 941. The p-type impurities are implanted in the surface portion of the drift layer 823. Further, a drive-in process is performed to diffuse the p-type impurities, which are implanted in the surface portion of the drift layer 823, in the width direction (X-axis direction) and depth direction (Z-axis direction) of the drift layer 823. The well regions 80 and the exposed surfaces 90s (not shown) between the well regions 80 adjacent in the Y-axis direction are formed through the steps described above. The fourth resist mask 940 is removed after the formation of the well regions 80.

In the present embodiment, when ion implantation is performed with the fourth resist mask 940, the p-type impurities are implanted, for example, once. When ion implantation is performed with the fourth resist mask 940, the p-type impurities may be implanted, for example, more than once. As the number of times the p-type impurities are implanted increases, the thickness HW of the well region 80 increases. The number of times implantation is performed and the ratio of the width of the openings 941 to the width of the inter-trench regions 27 and the trench-sideward regions 28 may be changed in accordance with the shape of the well regions 80.

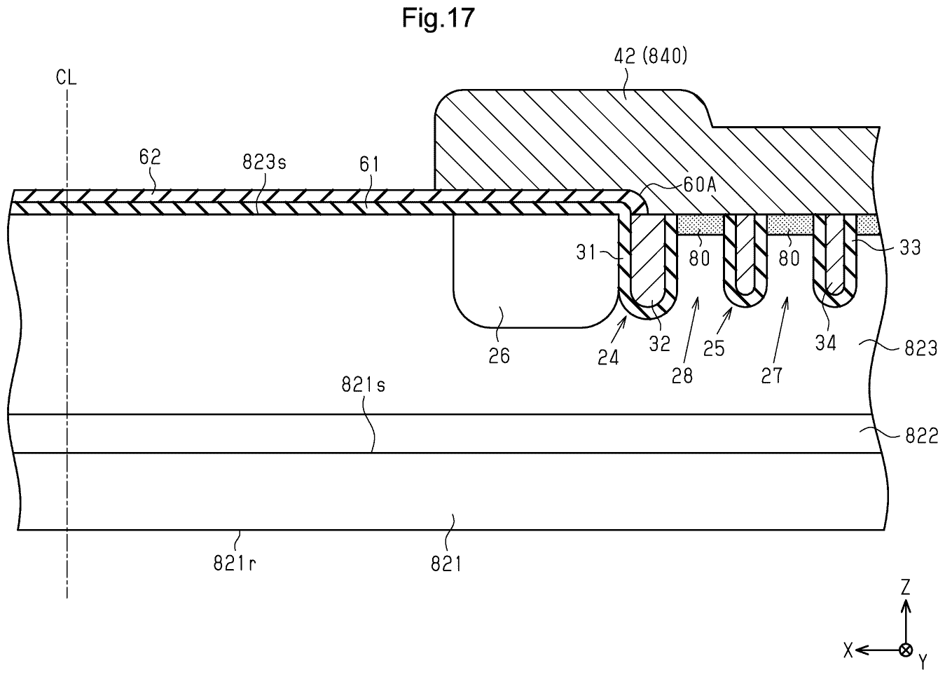

As shown in FIG. 17, CVD is performed to form the second base electrode film 840 on the well surface 80s of each well region 80, the exposed surfaces 90s (not shown), the isolation electrode 32, the embedded electrodes 34, and the surface insulating layer 60. The second base electrode film 840 is in ohmic contact with the well surface 80s of each well region 80, the isolation electrode 32, and the embedded electrodes 34. This electrically connects the second base electrode film 840 to the isolation electrode 32 and the embedded electrode 34. The second base electrode film 840 is electrically insulated from the peripheral well region 26. In the method for manufacturing the semiconductor device in accordance with the present embodiment, the second base electrode film 840 corresponds to “the first electrode.”

The second base electrode film 840 is formed by a stack of a first electrode film (not shown), a second electrode film (not shown), and a third electrode film (not shown).

The first electrode film is formed to contact the well surface 80s of each well region 80, the exposed surfaces 90s (not shown), the isolation electrode 32, the embedded electrodes 34, and the surface insulating layer 60. In the present embodiment, the first electrode film is formed from, for example, a material including Ti. The second electrode film is formed on the first electrode film. In the present embodiment, the second electrode film is formed from, for example, a material including TiN. The third electrode film is formed on the second electrode film. In the present embodiment, the third electrode film is formed from a material including Al.

The first electrode film, the second electrode film, and the third electrode film are each formed, for example, through at least one of sputtering, vapor deposition, and plating. In the present embodiment, the first electrode film, the second electrode film, and the third electrode film are each formed through sputtering.

Although not shown in the drawings, a sixth resist mask is then formed on the second base electrode film 840. The sixth resist mask does not cover the peripheral part of the second base electrode film 840. Etching is performed with the sixth resist mask to remove the peripheral part of the second base electrode film 840. This forms the anode 42.

Although not shown in the drawings, the method for manufacturing the semiconductor device 10 includes forming the surface protective layer 70, forming the cathode 41, and performing dicing.

The surface protective layer 70 is formed after the second base electrode film 840 is formed. For example, CVD is performed to form the surface protective layer 70 on the surface insulating layer 60 and the second base electrode film 840.

When forming the cathode 41, sputtering is performed to form the cathode 41 on the wafer back surface 821r of the semiconductor wafer 821. The cathode 41 is in ohmic contact with the wafer back surface 821r of the semiconductor wafer 821.

The dicing is performed after the surface protective layer 70 is formed. For example, a dicing blade is used to cut the surface protective layer 70, the drift layer 823, the buffer layer 822, and the cathode 41 along a cutting line CL indicated by the single-dashed line in FIG. 17. The semiconductor device 10 is manufactured through the steps described above.

### Operation

The operation of the present embodiment will now be described.

In the semiconductor device 10, the p-type well regions 80 are arranged in the parts of the surface 23s of the n-type drift layer 23 where the inter-trench regions 27 are located. Thus, the surface 23s of the drift layer 23 includes the well surfaces 80s, which are formed in the p-type well regions 80, and the exposed surfaces 90s, which are formed by the n-type the drift layer 23. The surface 23s of the drift layer 23 is in ohmic contact with the anode 42 at the well surfaces 80s and in Schottky contact with the anode 42 at the exposed surfaces 90s.

In the present embodiment, the well regions 80 are formed extending in the Y-axis direction, which intersects the direction in which the trenches 25 extend (i.e., X-axis direction) and are apart in the direction in which the trenches 25 extend (i.e., X-axis direction). As shown in FIG. 2, this forms first regions R1, which are in ohmic contact with the anode 42, and second regions R2, which are in Schottky contact with the anode 42. Both the first regions R1 and the second regions R2 are adjacent to the same trench 25. The first regions R1 and the second regions R2 are arranged alternately in the direction in which the trenches 25 extend.

More specifically, as shown in the cross-sectional view of FIG. 3, in each first region R1, the well regions 80 are formed in the entire surface 23s of the drift layer 23 in the inter-trench regions 27 and in the trench-sideward regions 28. The entire surface 23s of the drift layer 23 in each first region R1 includes the well surfaces 80s and is in ohmic contact with the anode 42. In each first region R1, the well surfaces 80s, which are in ohmic contact with the anode 42, are adjacent to the side walls 25a of the trenches 25.

As shown in the cross-sectional view of FIG. 5, in each second region R2, the entire surface 23s of the drift layer 23 between the adjacent trenches 25 is of the n-type. The entire surface 23s of the drift layer 23 in each second region R2 includes the exposed surfaces 90s and is in Schottky contact with the anode 42. In each second region R2, the exposed surfaces 90s, which are in Schottky contact with the anode 42, are adjacent to the side walls 25a of the trenches 25.

As described above, in the present embodiment, the first regions R1, which are in ohmic contact with the anode 42, and the second regions R2, which are in Schottky contact with the anode 42, are both adjacent to the side walls 25a of the same trench 25. In this case, the first regions R1, which are in ohmic contact with the anode 42, acquire the capability for suppressing leakage current. Further, the second regions R2, which are in Schottky contact with the anode 42, acquire the capability for reducing the forward voltage drop VF. In particular, the second regions R2, which include the side walls 25a adjacent to the trenches 25, strengthens the capability for reducing the forward voltage drop VF.

In the present embodiment, adjustment of the total area S1 of the well surfaces 80s of the well regions 80 facilitates adjustment of the capability for reducing the forward voltage drop VF and the capability for suppressing the leakage current. The capability for reducing the forward voltage drop VF is strengthened by forming the well regions 80 so that the total area S1 of the well surfaces 80s decreases. When decreasing the total area S1 of the well surfaces 80s, the total area S2 of the exposed surfaces 90s is relatively increased. Enlargement of the exposed surfaces 90s enlarges the second regions R2, which are in Schottky contact with the anode 42, and reduces the first regions R1, which are in ohmic contact with the anode 42. This strengthens the capability for reducing the forward voltage drop VF and weakens the capability for suppressing the leakage current.

The capability for suppressing the leakage current is strengthened by forming the well regions 80 so that the total area S1 of the well surfaces 80s increases. An increase in the total area S1 of the well surfaces 80s enlarges the first regions R1, which are in ohmic contact with the anode 42, and reduces the second regions R2, which are in Schottky contact with the anode 42. This strengthens the capability for suppressing the leakage current and weakens the capability for reducing the forward voltage drop VF.

The present embodiment has the advantages described below.

(1) The semiconductor device 10 includes the semiconductor substrate 21 of the first conductive type including the substrate front surface 21s and the substrate back surface 21r, the drift layer 23 of the first conductive type formed on the substrate front surface 21s, the anode 42 formed on the surface 23s of the drift layer 23, the cathode 41 formed on the substrate back surface 21r, the trenches 25 extending in the first direction that is orthogonal to the thickness direction of the drift layer 23 and spaced apart in the second direction that is orthogonal to the drift layer 23 and to the first direction, the insulating layer 33 covering the bottom walls 25b and the side walls 25a of the trenches 25, the embedded electrode 34 formed in the insulating layer 33 and contacting the anode 42, and the well regions 80 of the second conductive type formed in parts of the surface 23s of the drift layer 23. The well regions 80 extend in a direction intersecting the first direction and are spaced apart in the first direction. The well regions 80 include the well surfaces 80s formed in parts of the surface 23s of the drift layer 23 and the well ends 80e contacting the insulating layer 33 of the trenches 25. The surface 23s of the drift layer 23 is in ohmic contact with the anode 42 at the well surfaces 80s and is in Schottky contact with the anode 42 at the exposed surfaces 90s located between the well surfaces 80s.

In this structure, the well regions 80 may be formed to decrease the total area S1 of the well surfaces 80s in order to strengthen the capability for reducing the forward voltage drop VF. Further, the well regions 80 may be formed to increase the total area S1 of the well surfaces 80s in order to strengthen the capability for suppressing leakage current. Accordingly, adjustment of the total area S1 of the well surfaces 80s of the well regions 80 facilitates adjustment of the capability for reducing the forward voltage drop VF and the capability for suppressing the leakage current.

(2) The well region 80 extends in a direction intersecting the first direction and spans across one of the trenches 25 without overlapping with the one of the trenches 25. With this structure, the first regions R1, which are in ohmic contact with the anode 42, and the second regions R2, which are in Schottky contact with the anode 42, may be formed adjacent to two opposite sides of the same trench 25 in the X-axis direction. This results in advantage (1) being further prominent.

(3) The well regions 80 extend in the second direction, that is, in a direction orthogonal to the trenches 25. In a cross section taken orthogonal to the trenches 25 such as that shown in FIG. 3, this structure restricts the formation of both the well surface 80s, which is in ohmic contact with the anode 42, and the exposed surface 90s, which is in Schottky contact with the anode 42, in the same inter-trench region 27. In this case, the capability for suppressing leakage current in the first region R1, which is in ohmic contact with the anode 42, is further improved.

(4) The well regions 80 are spaced apart at equal intervals in the first direction. In this case, the total area S1 of the well surfaces 80s may be readily adjusted by changing the first direction length W1 of each well surface 80s.

### MODIFIED EXAMPLES

The above embodiments may be modified as described below. The above-described embodiments and the modified examples described below may be combined as long as there is no technical contradiction.

The conductive type may be inverted in the semiconductor substrate 21, the buffer layer 22, the drift layer 23, the peripheral well region 26, and the well regions 80. That is, the p-type regions may be changed to n-type regions, and the n-type regions may be changed to p-type regions.

### Modified Examples Related to the Well Regions

The well regions 80 may be of any shape and arrangement. For example, the well regions 80 do not have to be aligned in a specific direction with the trenches 25 located in between. In an example, the well surfaces 80s and the exposed surfaces 90s in two inter-trench regions 27 that are adjacent to each other in the X-axis direction may be arranged in a zigzagged manner.

In each well region 80, the width W1 of the well surface 80s may be constant throughout the entire range of the corresponding inter-trench region 27 or vary partially or entirely in the range. In each well region 80, the thickness HW of the well region 80 may be constant throughout the entire range of the corresponding inter-trench region 27 or vary partially or entirely in the range.

The cross-sectional shape of the well region 80 as viewed in the X-axis direction, that is, the shape of the cross-section in the X-axis direction (second direction), does not have to be semicircular. For example, the well region 80 may have a cross-sectional shape defined as an inner region of an arc of which two ends are located in the well surface 80s.

The two ends of each well region 80 define the two well ends 80e. At least one of the two well ends 80e is in contact with the insulating layer 33 of a trench 25. When one of the well ends 80e is in contact with the insulating layer 33 of a trench 25, the other well end 80e does not have to be in contact with the insulating layer 33 of a trench 25.

### Modified Examples of the Trenches

The trenches 25 may extend in the Y-axis direction in plan view, and each trench 25 may be connected to the adjacent trench 25 in the X-axis direction to form a lattice pattern. Each trench 25 have any shape as long as it includes a part extending in the Y-axis direction.

As long as the isolation trench 24 surrounds the trenches 25, the isolation trench 24 may have any closed shape in plan view. In an example, the isolation trench 24 may be formed so that the parts connecting two trenches 25 that are adjacent to each other in the X-axis direction are curved.

The phrase “in the upper direction from” as used in this specification also includes the meaning of “toward the upper side from” unless otherwise indicated in the context. Accordingly, the phrase of “first layer formed on second layer” may mean that the first layer is formed directly contacting the second layer in one embodiment and that the first layer is located above the second layer without contacting the second layer in another embodiment. That is, in a structure including a first layer and a second layer, the phrase “in the upper direction from” may include a further layer between the first and second layers.

The Z-axis direction as referred to in this specification does not necessarily have to be the vertical direction and does not necessarily have to fully coincide with the vertical direction. Accordingly, in the structures disclosed above (e.g., structure shown in FIG. 1), upward and downward in the Z-axis direction as referred to in this specification is not limited to upward and downward in the vertical direction. For example, the X-axis direction may be the vertical direction. Alternatively, the Y-axis direction may be the vertical direction.

In this disclosure, “at least one of A and B” should be understood to mean “only A, only B, or both A and B.”

### CLAUSES

Technical concepts that can be understood from each of the above embodiments and modified examples will now be described. Reference characters shown in parenthesis in the clauses described below denote corresponding elements of the embodiments described above. The reference characters are given as examples to aid understanding and not intended to limit elements to the elements denoted by the reference characters.

### Clause 1

A semiconductor device (10), including:
a semiconductor substrate (21) of a first conductive type (n) including a substrate front surface (21s) and a substrate back surface (21r) opposite the substrate front surface (21s);
a semiconductor layer (23) of the first conductive type (n) formed on the semiconductor front surface (21s) and including a surface (23s);
a first electrode (42) formed on the surface (23s) of the semiconductor layer (23);
a second electrode (41) formed on the substrate back surface (21r);
trenches (25) extending in a thickness direction of the semiconductor layer (23) from the surface (23s) of the semiconductor layer (23) and extending in a first direction that is orthogonal to the thickness direction of the semiconductor layer (23), in which the trenches (25) are spaced apart in a second direction that is orthogonal to the thickness direction of the semiconductor layer (23) and to the first direction;
an insulating layer (33) covering a bottom wall (25b) and side walls (25a) of each of the trenches (25);
a third electrode (34) formed in the insulating layer (33) and contacting the first electrode (42); and
a well region (80) of a second conductive type (p) formed in a part of the surface (23s) of the semiconductor layer (23), where
the well region (80) is one of multiple well regions (80) extending in a direction intersecting the first direction and spaced apart in the first direction,
the well region (80) includes a well surface (80s) forming a part of the surface (23s) of the semiconductor layer (23) and well ends (80e) contacting the insulating layer (33) of one of the trenches (25), in which the well surface (80s) is one of multiple well surfaces (80s), and
the surface (23s) of the semiconductor layer (23) is in ohmic contact with the first electrode (42) at the well surfaces (80s), and the surface (23s) of the semiconductor layer (23) is in Schottky contact with the first electrode (42) at an exposed surface (90s) located between the multiple well surfaces (80s).

### Clause 2

The semiconductor device (10) according to clause 1, where the well region (80) extends in a direction intersecting the first direction and spans across one of the trenches (25) without overlapping with the one of the trenches.

### Clause 3

The semiconductor device (10) according to clause 1 or 2, where the well region (80) extends in the second direction.

### Clause 4

The semiconductor device (10) according to any one of clauses 1 to 3, where the multiple wells regions (80) are spaced apart at equal intervals in the first direction.

### Clause 5

The semiconductor device (10) according to any one of clauses 1 to 4, where a total area (S1) of the well surfaces (80s) is less than a total area (S2) of the exposed surface (90s).

### Clause 6

The semiconductor device (10) according to any one of clauses 1 to 4, where an area ratio (S1/S2) of a total area (S1) of the well surfaces (80s) to a total area (S2) of the exposed surface (90s) satisfies 0<S1/S2≤100.

### Clause 7

The semiconductor device (10) according to clause 5 or 6, where a first direction length (W1) of the well surface (80s) is less than a first direction length (W2) of the exposed surface (90s) in the surface (23s) of the semiconductor layer (23).

### Clause 8

The semiconductor device (10) according to any one of clauses 1 to 4, where a total area (S1) of the well surfaces (80s) is greater than a total area (S2) of the exposed surface (90s).

### Clause 9

The semiconductor device (10) according to clause 8, where an area ratio (S1/S2) of the total area (S1) of the well surfaces (80s) to the total area (S2) of the exposed surface (90s) satisfies 1<S1/S2≤100.

### Clause 10

The semiconductor device (10) according to clause 8 or 9, where a first direction length (W1) of the well surface (80s) is greater than a first direction length (W2) of the exposed surface (90s) in the surface (23s) of the semiconductor layer (23).

### Clause 11

The semiconductor device (10) according to any one of clauses 1 to 10, where a first direction length (W1) of the well surface (80s) is less than a distance (D1) between adjacent ones of the trenches (25).

### Clause 12

The semiconductor device (10) according to any one of clauses 1 to 10, where a first direction length (W1) of the well surface (80s) is greater than a distance (D1) between adjacent ones of the trenches (25).

### Clause 13

The semiconductor device (10) according to any one of clauses 1 to 12, where a first direction length (W1) of the well surface (80s) is greater than a second direction length (L1) of one of the trenches (25).

### Clause 14

The semiconductor device (10) according to any one of clauses 1 to 13, where a thickness (HW) of the well region (80) is less than or equal to one-half of a depth (HT) of one of the trenches (25).

### Clause 15

The semiconductor device (10) according to any one of clauses 1 to 14, where the insulating layer (33) of one of the trenches (25) includes:
first parts (33a) contacting the well ends (80e) of the well region (80); and
a second part (33b) contacting the semiconductor layer (23) and located between the first parts (33a).

### Clause 16

A method for manufacturing a semiconductor device (10), the method including:
preparing a semiconductor substrate (21) of a first conductive type including a substrate front surface (21s) and a substrate back surface (21r) opposite the substrate front surface (21s);
forming a semiconductor layer (23) that is of the first conductive type and includes a surface (23s) on the semiconductor front surface (21s);
forming a first electrode (42) on the surface (23s) of the semiconductor layer (23);
forming a second electrode (41) on the substrate back surface (21r);
forming trenches (25) that extend in a thickness direction (Z-axis direction) of the semiconductor layer (23) from the surface (23s) of the semiconductor layer (23) and extend in a first direction (Y-axis direction) orthogonal to the thickness direction (Z-axis direction) of the semiconductor layer (23), in which the trenches (25) are spaced apart in a second direction (X-axis direction) orthogonal to the thickness direction (Z-axis direction) of the semiconductor layer (23) and to the first direction (Y-axis direction);
forming an insulating layer (33) covering a bottom wall (25b) and a side wall (25a) of each of the trenches (25);
forming a third electrode (34) that contacts the first electrode (42) in the insulating layer (33); and
forming a well region (80) of a second conductive type in an inter-trench region (27) that is a part of the surface (23s) of the semiconductor layer (23) between adjacent ones of the trenches (25), where
the well region (80) includes a well surface (80s) forming a part of the surface (23s) of the semiconductor layer (23) and well ends (80e) contacting the insulating layer (33) of one of the trenches (25), in which the well surface (80s) is one of multiple well surfaces (80s), and
the first electrode (42) is formed so that the surface (23s) of the semiconductor layer (23) is in ohmic contact with the first electrode (42) at the well surfaces (80s), and the surface (23s) of the semiconductor layer (23) is in Schottky contact with the first electrode (42) at an exposed surface (90s) located between the multiple well surfaces (80s).

Exemplary descriptions are given above. In addition to the elements and methods (manufacturing processes) described to illustrate the technology of this disclosure, a person skilled in the art would recognize the potential for a wide variety of combinations and substitutions. All replacements, modifications, and variations within the scope of the claims are intended to be encompassed in the present disclosure.

What is claimed is:

1. A semiconductor device, comprising:
a semiconductor substrate of a first conductive type including a substrate front surface and a substrate back surface opposite the substrate front surface;
a semiconductor layer of the first conductive type formed on the semiconductor front surface and including a surface;
a first electrode formed on the surface of the semiconductor layer;
a second electrode formed on the substrate back surface;
trenches extending in a thickness direction of the semiconductor layer from the surface of the semiconductor layer and extending in a first direction that is orthogonal to the thickness direction of the semiconductor layer, wherein the trenches are spaced apart in a second direction that is orthogonal to the thickness direction of the semiconductor layer and to the first direction;
an insulating layer covering a bottom wall and side walls of each of the trenches;
a third electrode formed in the insulating layer and contacting the first electrode; and
a well region of a second conductive type formed in a part of the surface of the semiconductor layer, wherein
the well region is one of multiple well regions extending in a direction intersecting the first direction and spaced apart in the first direction;
the well region includes a well surface forming a part of the surface of the semiconductor layer and well ends contacting the insulating layer of one of the trenches, wherein the well surface is one of multiple well surfaces, and
the surface of the semiconductor layer is in ohmic contact with the first electrode at the well surfaces, and the surface of the semiconductor layer is in Schottky contact with the first electrode at an exposed surface located between the multiple well surfaces.

2. The semiconductor device according to claim 1, wherein the well region extends in a direction intersecting the first direction and spans across one of the trenches without overlapping with the one of the trenches.

3. The semiconductor device according to claim 1, wherein the well region extends in the second direction.

4. The semiconductor device according to claim 1, wherein the multiple wells regions are spaced apart at equal intervals in the first direction.

5. The semiconductor device according to claim 1, wherein a total area (S1) of the well surfaces is less than a total area (S2) of the exposed surface.

6. The semiconductor device according to claim 1, wherein an area ratio (S1/S2) of a total area (S1) of the well surfaces to a total area (S2) of the exposed surface satisfies 0<S1/S2≤100.

7. The semiconductor device according to claim 1, wherein a total area (S1) of the well surfaces is greater than a total area (S2) of the exposed surface.

8. The semiconductor device according to claim 7, wherein an area ratio (S1/S2) of the total area (S1) of the well surfaces to the total area (S2) of the exposed surface satisfies 1<S1/S2≤100.

9. The semiconductor device according to claim 1, wherein a first direction length of the well surface is less than a distance between adjacent ones of the trenches.

10. The semiconductor device according to claim 1, wherein a first direction length of the well surface is greater than a distance between adjacent ones of the trenches.

11. The semiconductor device according to claim 1, wherein a first direction length of the well surface is greater than a second direction length of one of the trenches.

12. The semiconductor device according to claim 1, wherein a thickness of the well region is less than or equal to one-half of a depth of one of the trenches.

13. The semiconductor device according to claim 1, wherein the insulating layer of one of the trenches includes:
first parts contacting the well ends of the well region; and
a second part contacting the semiconductor layer and located between the first parts.
